(19) United States
(12) Patent Application Publication
(10) Pub. No.: US 2025/0039445 A1
(43) Pub. Date: Jan. 30, 2025

(54) METHODS AND APPARATUSES FOR ENCODING/DECODING A VOLUMETRIC CONTENT

(71) Applicant: InterDigital CE Patent Holdings, SAS, Paris (FR)

(72) Inventors: Didier Doyen, Cesson-Sevigne (FR); Amandine Chauveau, Bordeaux (FR); Vincent Brac De La Perriere, Rennes (FR); Bertrand Chupeau, Rennes (FR)

(21) Appl. No.: 18/705,059

(22) PCT Filed: Oct. 18, 2022
(86) PCT No.: PCT/EP2022/078900

§ 371 Date: Apr. 26, 2024

(30) Foreign Application Priority Data
Oct. 28, 2021 (EP) 21306517.0

(51) Int. Cl. H04N 19/597; G03H 1/04

(52) U.S. Cl. CPC H04N 19/597; G03H 1/0406

(57) ABSTRACT

A method and an apparatus for reconstructing a Computer-Generated Hologram from a multiple plane image are provided. Reconstructing the Computer-Generated Hologram comprises decoding data representative of at least one patch of at least one layer of the multiple plane image, the data comprising a first location for placing the patch in a first image of the multiple plane image, the first location being used for placing reconstructed content of the patch in a 3D scene, and determining for the at least one patch a second location for placing the patch in a second image, the second image being intended to be used for determining the Computer-Generated Hologram.

### TECHNICAL FIELD

The present embodiments generally relate to the domain of three-dimensional (3D) scene and volumetric video content, including computer-generated holography. The present embodiments generally relate to methods and apparatuses for encoding and decoding multiple plane images representative of a 3D scene. More particularly, the present embodiments relate to methods and apparatuses for encoding/decoding/reconstructing Computer Generated Hologram from multiple plane images.

### BACKGROUND

The present section is intended to introduce the reader to various aspects of art, which may be related to various aspects of the present principles that are described and/or claimed below. This discussion is believed to be helpful in providing the reader with background information to facilitate a better understanding of the various aspects of the present principles. Accordingly, it should be understood that these statements are to be read in this light, and not as admissions of prior art.

The principle of Digital Holography (DH) is to reconstruct the exact same light wave front emitted by a 3-dimensional object. This wave front carries all the information on parallax and distance. Both types of information are lost by 2-dimensional conventional imaging systems (digital cameras, 2 dimensional images . . . ), and only parallax can be retrieved using recent multi-view light-field displays. The impossibility of such displays to render both parallax and depth cues leads to convergence-accommodation conflict, which can cause eye strain, headache, nausea and lack of realism.

Holography is historically based on the recording of the interferences created by a reference beam, coming from a coherent light source, and an object beam, formed by the reflection of the reference beam on the subject. The interference pattern was recorded in photosensitive material, and locally (microscopically) looks like a diffraction grating, with a grating pitch of the order of the wavelength used for the recording. Once this interference pattern has been recorded, its illumination by the original reference wave re-creates the object beam, and the original wave front of the 3D object.

The original concept of holography evolved into the modern concept of Digital Holography. The requirements of high stability and photosensitive material made holography impractical for the display of dynamic 3D content. With the emergence of liquid crystal displays, the possibility of modulating the phase of an incoming wave front, and thus of shaping it at will, made it possible to recreate interference patterns on dynamic devices. The hologram can this time be computed and referred to as a Computer-Generated Hologram (CGH). The synthesis of CGH requires the computation of the interference pattern that was previously recorded on photosensitive material, which can be done through various methods using Fourier optics. The object beam (i.e., the 3D image) can be obtained, for example, by illuminating a liquid crystal on silicon spatial light modulator (LCOS SLM) display bearing the CGH with the reference beam.

There are several ways to calculate a CGH depending on the source it is considering. When applied to a point cloud, each point is considered as a light source. The CGH corresponds to the sum of the contribution of each point considered a light source. The calculation cost is huge since it is in the magnitude of the number of points of the point cloud time the resolution in pixels of the hologram plane.

To reduce this amount of calculation a layer-based approach is preferred. The principle is to calculate the hologram by applying an FFT-based processing to layers and not to pixels. A layer is a group of pixels at a given depth, all layers are propagated to the hologram plane using a single FFT-based operation. The 3D content must be then organized as a group of layers, each pixel belonging to one layer is considered to have the same depth.

The CGH calculation time for a volumetric content can be extremely huge especially when the input is in a layer-based format. The CGH calculation time for a layer-based format is proportional to the number of layers, considering that the layers have the same size. When the real-time aspect is required to display the hologram, it is necessary to reduce the time to compute the CGH. Thus, there is a need to improve the state of the art.

### SUMMARY

According to an aspect, a method for reconstructing a Computer-Generated Hologram from a multiple plane image is provided wherein reconstructing the Computer-Generated Hologram comprises decoding data representative of at least one patch of at least one layer of the multiple plane image, said data comprising a first location for placing said patch in a first image of the multiple plane image, said first location being used for placing reconstructed content of said patch in a 3D scene, determining for said at least one patch a second location for placing said patch in a second image, said second image being intended to be used for determining the Computer-Generated Hologram.

According to another aspect, an apparatus for reconstructing a Computer-Generated Hologram from a multiple plane image is provided, the apparatus comprising one or more processors configured to decode data representative of at least one patch of at least one layer of the multiple plane image, said data comprising a first location for placing said patch in a first image of the multiple plane image, said first location being used for placing reconstructed content of said patch in a 3D scene, determine for said at least one patch a second location for placing said patch in a second image, said second image being intended to be used for determining the Computer-Generated Hologram.

According to another aspect, a method for encoding a multiple plane image is provided, wherein the encoding comprises encoding in a bitstream, data representative of at least one patch of at least one layer of a multiple plane image, said data comprising a first location for placing said patch in a first image of the multiple plane image, said first location being used for placing reconstructed content of said patch in a 3D scene, determining at least one item of information allowing to determine, for at least said at least one patch, a second location for placing said patch in a second image when reconstructing a Computer-Generated Hologram using said second image, encoding said at least one item of information in the bitstream.

According to another aspect, an apparatus for encoding a multiple plane image is provided, wherein the apparatus comprises one or more processors configured to encode in a bitstream, data representative of at least one patch of at least one layer of a multiple plane image, said data comprising a first location for placing said patch in a first image of the multiple plane image, said first location being used for placing reconstructed content of said patch in a 3D scene, determine at least one item of information allowing to determine, for at least said at least one patch, a second location for placing said patch in a second image when reconstructing a Computer-Generated Hologram using said second image, encode said at least one item of information in the bitstream.

According to another aspect, one or more embodiments relate to a bitstream that comprises data representative of at least one patch of at least one layer of a multiple plane image, said data comprising a first location for placing said patch in a first image of the multiple plane image, said first location being used for placing reconstructed content of said patch in a 3D scene, data representative of at least one item of information allowing to determine, for at least said at least one patch, a second location for placing said patch in a second image when reconstructing a Computer-Generated Hologram using said second image.

One or more embodiments also provide a computer program comprising instructions which when executed by one or more processors cause the one or more processors to perform any one of the methods according to any of the embodiments described above. One or more of the present embodiments also provide a computer readable storage medium having stored thereon instructions for encoding or decoding multiple plane images or Computer-Generated Holograms, or reconstructing Computer Generated Holograms according to the methods described above. One or more embodiments also provide a computer readable storage medium having stored thereon a bitstream generated according to the methods described above. One or more embodiments also provide a method and apparatus for transmitting or receiving the bitstream generated according to the methods described above.

### BRIEF DESCRIPTION OF THE DRAWINGS

The present disclosure will be better understood, and other specific features and advantages will emerge upon reading the following description, the description making reference to the annexed drawings wherein:

FIG. 1 shows an example architecture of a device which may be configured to implement a method described in relation with any one of FIG. 2-17, according to a non-limiting embodiment of the present principles,

FIG. 2 illustrates an example of a set of layers of an MPI content,

FIG. 3 illustrates an example of an MIV content based on different patches,

FIG. 4 illustrates a relation between the size of the image and the calculation time of a CGH from that image,

FIG. 5 illustrates an overview of a workflow for encoding/decoding/reconstructing CGH from MPI, according to an embodiment,

FIG. 6 illustrates a method for encoding MPI content that can be used for reconstructing a CGH, according to an embodiment,

FIG. 7 illustrates a method for reconstructing a CGH from a received MPI content, according to an embodiment,

FIG. 8 illustrates an example of two layers of an MPI corresponding to two depths,

FIG. 9 illustrates an example of the two different layers of an MPI with active areas included in bounding boxes,

FIG. 10 illustrates an example of a re-arrangement of the two layers reducing the corresponding size of the layer image while keeping all the useful data for reconstructing the content,

FIG. 11 illustrates an example of re-arranged layers wherein patches are separated by a non-overlapping area,

FIG. 12 illustrates a method for reconstructing a CGH from a received MPI content, according to another embodiment,

FIG. 13 illustrates a method for reconstructing a CGH from a received MPI content, according to another embodiment,

FIG. 14 illustrates a method for reconstructing a CGH from a received MPI content, according to another embodiment,

FIG. 15 shows two remote devices communicating over a communication network in accordance with an example of the present principles.

FIG. 16 shows the syntax of a signal in accordance with an example of the present principles.

FIG. 17 illustrates a method for determining second locations for patches in an image having a reduced size with respect to an image of a layer of an MPI.

### DETAILED DESCRIPTION

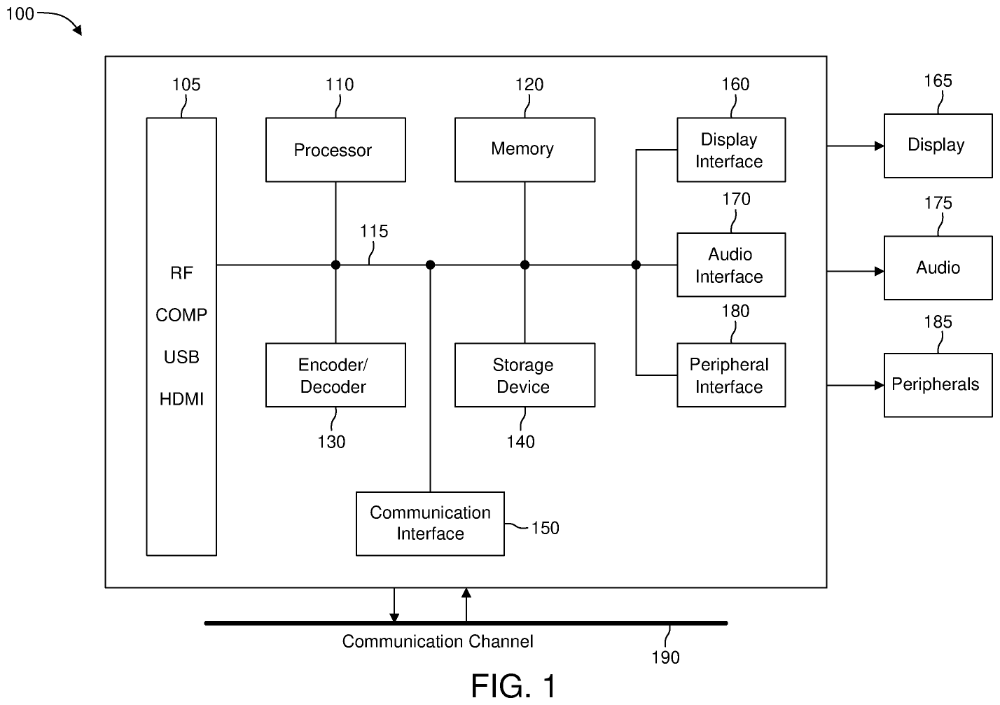

FIG. 1 illustrates a block diagram of an example of a system in which various aspects and embodiments can be implemented. System 100 may be embodied as a device including the various components described below and is configured to perform one or more of the aspects described in this application. Examples of such devices, include, but are not limited to, various electronic devices such as personal computers, laptop computers, smartphones, tablet computers, digital multimedia set top boxes, digital television receivers, personal video recording systems, connected home appliances, and servers. Elements of system 100, singly or in combination, may be embodied in a single integrated circuit, multiple ICs, and/or discrete components. For example, in at least one embodiment, the processing and encoder/decoder elements of system 100 are distributed across multiple ICs and/or discrete components. In various embodiments, the system 100 is communicatively coupled to other systems, or to other electronic devices, via, for example, a communications bus or through dedicated input and/or output ports. In various embodiments, the system 100 is configured to implement one or more of the aspects described in this application.

The system 100 includes at least one processor 110 configured to execute instructions loaded therein for implementing, for example, the various aspects described in this application. Processor 110 may include embedded memory, input output interface, and various other circuitries as known in the art. The system 100 includes at least one memory 120 (e.g., a volatile memory device, and/or a non-volatile memory device). System 100 includes a storage device 140, which may include non-volatile memory and/or volatile memory, including, but not limited to, EEPROM, ROM, PROM, RAM, DRAM, SRAM, flash, magnetic disk drive, and/or optical disk drive. The storage device 140 may include an internal storage device, an attached storage device, and/or a network accessible storage device, as non-limiting examples.

System 100 includes an encoder/decoder module 130 configured, for example, to process data to provide an encoded video/3D scene or decoded video/3D scene, and the encoder/decoder module 130 may include its own processor and memory. The encoder/decoder module 130 represents module(s) that may be included in a device to perform the encoding and/or decoding functions. As is known, a device may include one or both of the encoding and decoding modules. Additionally, encoder/decoder module 130 may be implemented as a separate element of system 100 or may be incorporated within processor 110 as a combination of hardware and software as known to those skilled in the art.

Program code to be loaded onto processor 110 or encoder/decoder 130 to perform the various aspects described in this application may be stored in storage device 140 and subsequently loaded onto memory 120 for execution by processor 110. In accordance with various embodiments, one or more of processor 110, memory 120, storage device 140, and encoder/decoder module 130 may store one or more of various items during the performance of the processes described in this application. Such stored items may include, but are not limited to, the input video/3D scene, the decoded video/3D scene or portions of the decoded video/3D scene, the bitstream, matrices, variables, and intermediate or final results from the processing of equations, formulas, operations, and operational logic.

In some embodiments, memory inside of the processor 110 and/or the encoder/decoder module 130 is used to store instructions and to provide working memory for processing that is needed during encoding or decoding. In other embodiments, however, a memory external to the processing device (for example, the processing device may be either the processor 110 or the encoder/decoder module 130) is used for one or more of these functions. The external memory may be the memory 120 and/or the storage device 140, for example, a dynamic volatile memory and/or a non-volatile flash memory. In several embodiments, an external non-volatile flash memory is used to store the operating system of a television. In at least one embodiment, a fast external dynamic volatile memory such as a RAM is used as working memory for video coding and decoding operations, such as for MPEG-2, (MPEG refers to the Moving Picture Experts Group, MPEG-2 is also referred to as ISO/IEC 13818, and 13818-1 is also known as H.222, and 13818-2 is also known as H.262), HEVC (HEVC refers to High Efficiency Video Coding, also known as H.265 and MPEG-H Part 2), or VVC (Versatile Video Coding, a new standard being developed by JVET, the Joint Video Experts Team).

The input to the elements of system 100 may be provided through various input devices as indicated in block 105. Such input devices include, but are not limited to, (i) a radio frequency (RF) portion that receives an RF signal transmitted, for example, over the air by a broadcaster, (ii) a Component (COMP) input terminal (or a set of COMP input terminals), (iii) a Universal Serial Bus (USB) input terminal, and/or (iv) a High Definition Multimedia Interface (HDMI) input terminal. Other examples, not shown in FIG. 1, include composite video.

In various embodiments, the input devices of block 105 have associated respective input processing elements as known in the art. For example, the RF portion may be associated with elements suitable for (i) selecting a desired frequency (also referred to as selecting a signal, or band-limiting a signal to a band of frequencies), (ii) down converting the selected signal, (iii) band-limiting again to a narrower band of frequencies to select (for example) a signal frequency band which can be referred to as a channel in certain embodiments, (iv) demodulating the down converted and band-limited signal, (v) performing error correction, and (vi) demultiplexing to select the desired stream of data packets. The RF portion of various embodiments includes one or more elements to perform these functions, for example, frequency selectors, signal selectors, band-limiters, channel selectors, filters, downconverters, demodulators, error correctors, and demultiplexers. The RF portion may include a tuner that performs various of these functions, including, for example, down converting the received signal to a lower frequency (for example, an intermediate frequency or a near-baseband frequency) or to baseband. In one set-top box embodiment, the RF portion and its associated input processing element receives an RF signal transmitted over a wired (for example, cable) medium, and performs frequency selection by filtering, down converting, and filtering again to a desired frequency band. Various embodiments rearrange the order of the above-described (and other) elements, remove some of these elements, and/or add other elements performing similar or different functions. Adding elements may include inserting elements in between existing elements, for example, inserting amplifiers and an analog-to-digital converter. In various embodiments, the RF portion includes an antenna.

Additionally, the USB and/or HDMI terminals may include respective interface processors for connecting system 100 to other electronic devices across USB and/or HDMI connections. It is to be understood that various aspects of input processing, for example, Reed-Solomon error correction, may be implemented, for example, within a separate input processing IC or within processor 110 as necessary. Similarly, aspects of USB or HDMI interface processing may be implemented within separate interface ICs or within processor 110 as necessary. The demodulated, error corrected, and demultiplexed stream is provided to various processing elements, including, for example, processor 110, and encoder/decoder 130 operating in combination with the memory and storage elements to process the datastream as necessary for presentation on an output device.

Various elements of system 100 may be provided within an integrated housing, Within the integrated housing, the various elements may be interconnected and transmit data therebetween using suitable connection arrangement 115, for example, an internal bus as known in the art, including the I2C bus, wiring, and printed circuit boards.

The system 100 includes communication interface 150 that enables communication with other devices via communication channel 190. The communication interface 150 may include, but is not limited to, a transceiver configured to transmit and to receive data over communication channel 190. The communication interface 150 may include, but is not limited to, a modem or network card and the communication channel 190 may be implemented, for example, within a wired and/or a wireless medium.

Data is streamed to the system 100, in various embodiments, using a Wi-Fi network such as IEEE 802.11 (IEEE refers to the Institute of Electrical and Electronics Engineers). The Wi-Fi signal of these embodiments is received over the communications channel 190 and the communications interface 150 which are adapted for Wi-Fi communications. The communications channel 190 of these embodiments is typically connected to an access point or router that provides access to outside networks including the Internet for allowing streaming applications and other over-the-top communications. Other embodiments provide streamed data to the system 100 using a set-top box that delivers the data over the HDMI connection of the input block 105. Still other embodiments provide streamed data to the system 100 using the RF connection of the input block 105. As indicated above, various embodiments provide data in a non-streaming manner. Additionally, various embodiments use wireless networks other than Wi-Fi, for example a cellular network or a Bluetooth network.

The system 100 may provide an output signal to various output devices, including a display 165, speakers 175, and other peripheral devices 185. The display 165 of various embodiments includes one or more of, for example, a touchscreen display, an organic light-emitting diode (OLED) display, a curved display, and/or a foldable display. The display 165 can be for a television, a tablet, a laptop, a cell phone (mobile phone), or other device, holographic displays including near-eye displays, head-up displays or TV displays. The display 165 can also be integrated with other components (for example, as in a smart phone), or separate (for example, an external monitor for a laptop). The other peripheral devices 185 include, in various examples of embodiments, one or more of a stand-alone digital video disc (or digital versatile disc) (DVR, for both terms), a disk player, a stereo system, and/or a lighting system. Various embodiments use one or more peripheral devices 185 that provide a function based on the output of the system 100. For example, a disk player performs the function of playing the output of the system 100.

In various embodiments, control signals are communicated between the system 100 and the display 165, speakers 175, or other peripheral devices 185 using signaling such as AV.Link, CEC, or other communications protocols that enable device-to-device control with or without user intervention. The output devices may be communicatively coupled to system 100 via dedicated connections through respective interfaces 160, 170, and 180. Alternatively, the output devices may be connected to system 100 using the communications channel 190 via the communications interface 150. The display 165 and speakers 175 may be integrated in a single unit with the other components of system 100 in an electronic device, for example, a television. In various embodiments, the display interface 160 includes a display driver, for example, a timing controller (T Con) chip.

The display 165 and speaker 175 may alternatively be separate from one or more of the other components, for example, if the RF portion of input 105 is part of a separate set-top box. In various embodiments in which the display 165 and speakers 175 are external components, the output signal may be provided via dedicated output connections, including, for example, HDMI ports, USB ports, or COMP outputs.

The embodiments can be carried out by computer software implemented by the processor 110 or by hardware, or by a combination of hardware and software. As a non-limiting example, the embodiments can be implemented by one or more integrated circuits. The memory 120 can be of any type appropriate to the technical environment and can be implemented using any appropriate data storage technology, such as optical memory devices, magnetic memory devices, semiconductor-based memory devices, fixed memory, and removable memory, as non-limiting examples. The processor 110 can be of any type appropriate to the technical environment, and can encompass one or more of microprocessors, general purpose computers, special purpose computers, and processors based on a multi-core architecture, as non-limiting examples.

An aim of the present disclosure is to reduce the global amount of time required to calculate a CGH. Since the time to calculate the contribution of a layer to the global CGH is linked to the size of the layer, an aim of the present disclosure is to optimize the size of each layer to reduce at the end the global calculation time.

Multi-plane Images is a data format used to represent a volumetric content. In E. Penner and L. Zhang, “Soft 3d reconstruction for view synthesis,” Proc. SIGGRAPH Asia, vol. 36, no. 6, 2017, Penner and Zhang have proposed a solution to generate such MPI from a multi-view content including a nonbinary parameter that represent a probability for a pixel to be at a given depth. The nonbinary information reflects the fact that there is no certainty that a pixel is at a given depth but more a probability that this pixel is at this depth. This nonbinary information is useful to correctly describe contours of objects.

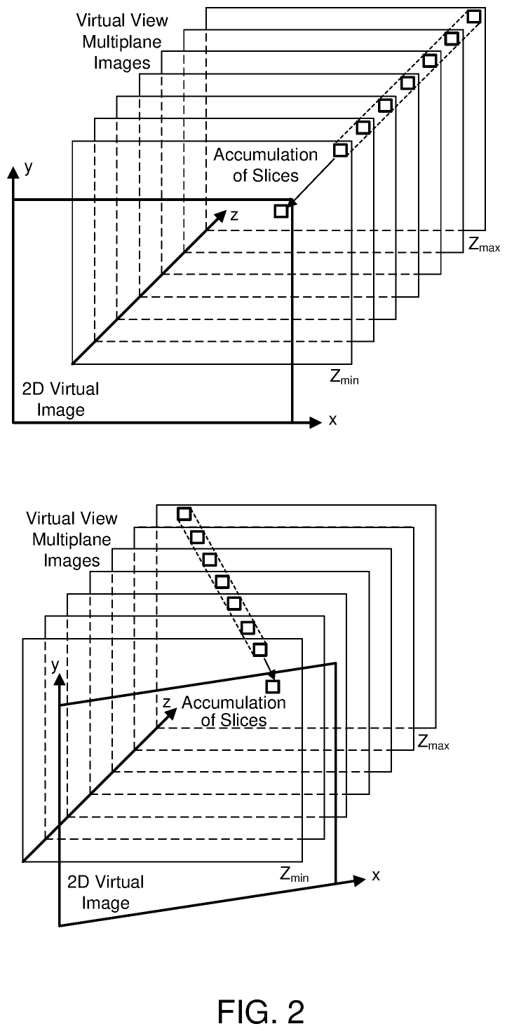

The MPI format is well adapted to a view synthesis application. In B. Vandame and al, “PIPELINE FOR REAL-TIME VIDEO VIEW SYNTHESIS,” Proc. ICME 2020, Vandame and al. shows how this MPI format can be used to generate real-time view synthesis. FIG. 2 illustrates a set of layers of an MPI content wherein each layer corresponds to a given depth z between a minimum depth zmin and a maximum depth zmax (top part). On the bottom part, the principle of a view synthesis from the MPI is presented. Small grey squares correspond to the successive information that is integrated from all the layers along the given viewpoint direction to synthetize one view of the given viewpoint.

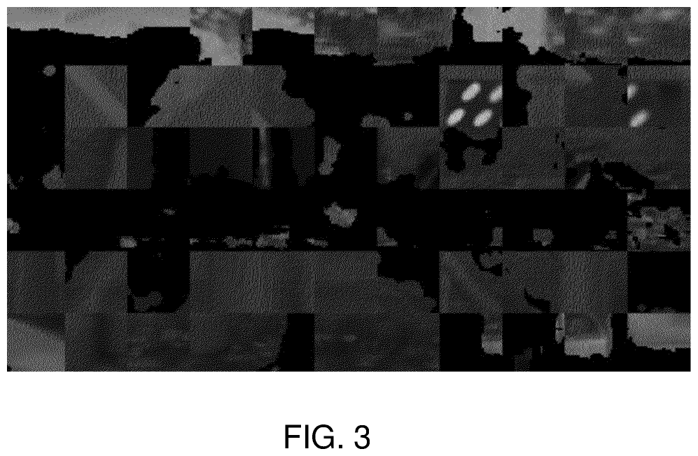

The MPI has been proposed as one input format for the MIV compression technology (ISO/IEC 23090-12:2021 (E) MPEG Immersive Video). The syntax of MIV has been adapted to integrate the alpha nonbinary parameter associated with the texture of each layer of the MPI. In case of MIV transmission only non-redundant MPI information are transmitted. The MIV content is a collection of patches such as illustrated in FIG. 3.

At the decoder side, for a view synthesis application, there is no need to reconstruct the whole MPI. At the decoding side, only required patches are decoded and the renderer performs the required view synthesis using the decoded patches.

Estimation of the Time to Calculate the CGH from an MPI

If the input is an MPI content, the CGH is calculated by performing the propagation of each layer at its respective distance to the CGH plane location. Since the calculation time is only dependent on the size of the layer, the whole calculation time for n layers of the same size is given by the following equation:

$$CTtot = {\sum }_{0}^{n - 1} CTlayer$$

Where CTtot is the total calculation time and CTlayer is the time to calculate one layer. Each layer having the same size.

If the layers do not have the same size, the total time is equal to the sum of individual time for each layer.

$$CTtot = {\sum }_{0}^{n - 1} CTlayer ( n )$$

Where CTlayer(n) is the time to calculate the layer n.

The CGH calculation time for a volumetric content can be extremely huge especially when the input is at the MPI format. As described above, the CGH calculation time for an MPI is proportional to the number of layers if the layers have the same size. When the real-time aspect is required to display the hologram, reducing the computing-time is desirable.

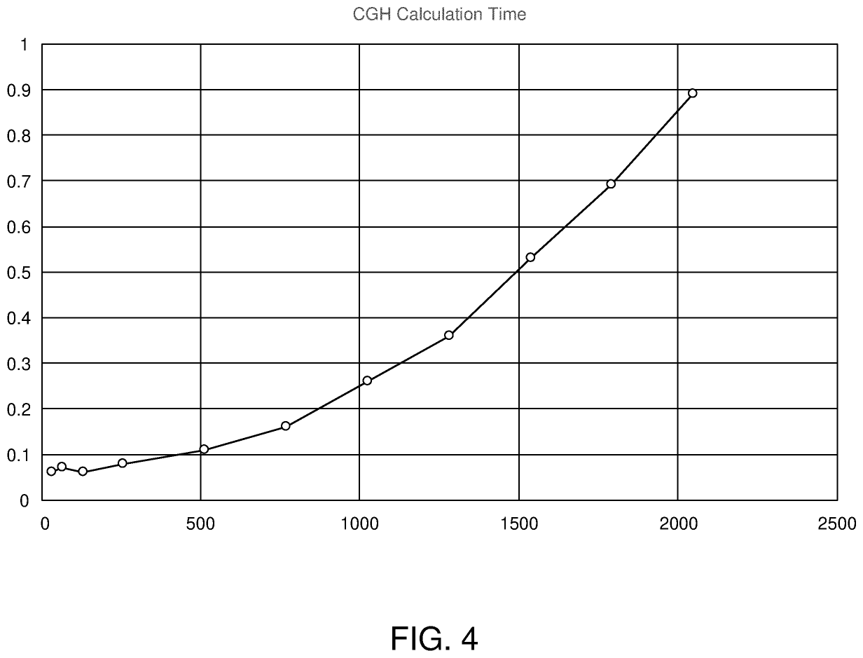

The calculation time of a CGH is directly correlated to the size of the picture. The curve illustrated on FIG. 4 gives the calculation time in second for a given size of a picture, based on a matlab code. The calculation time can be strongly reduced using GPU instead of matlab but the law between calculation time and size of the picture remains the same. The picture is a square picture, 1028 on horizontal axe means a picture of 1028*1028. The calculation time is given for a platform and a software, what is important to notice is the huge advantage to limit the size of the picture. This will be true whatever the platform. The calculation has been given for a Angular Spectrum algorithm as an example.

A method for encoding and a method for decoding volumetric content that allows to reconstruct a CGH are provided. An aim of these methods is to reduce the global amount of time required to calculate the CGH at the reconstruction. Since the time to calculate the contribution of a layer to the global CGH is linked to the size of the layer, it is an aim of the provided methods to minimize the size of each layer to reduce at the end the global calculation time.

When a MPI content is transmitted through the MIV standard, the different layers are split into a given number of patches. Each patch has its own metadata to store the depth associated to the patch and the position of the patch in the 3D scene.

According to an embodiment of the present disclosure, not only the physical place of the patch in the scene is associated to the patch of the MIV content but also another place in the layer, such position optimizing the calculation time of the CGH. The initial location of the patch in the scene is kept ensuring a repositioning at the end of the CGH calculation process but a second location is determined for the patch and used in case of CGH calculation.

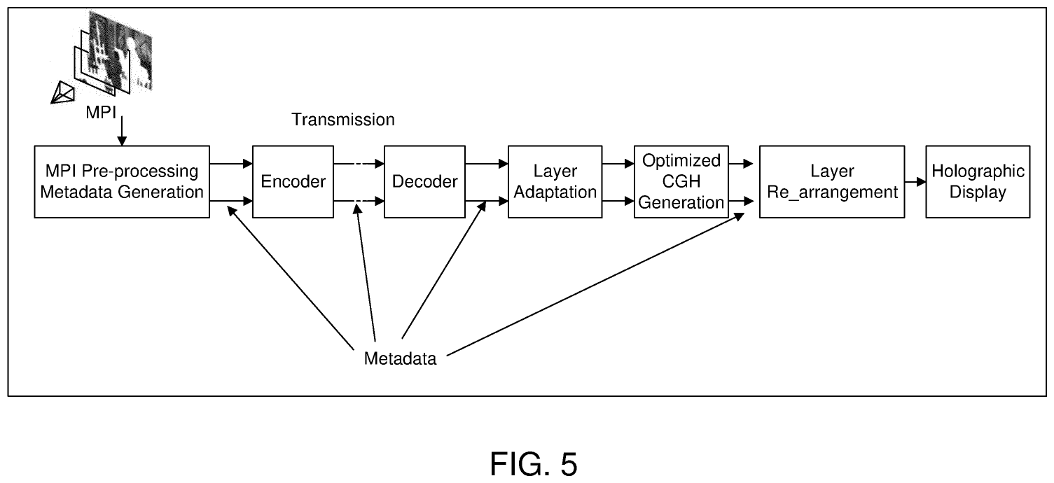

FIG. 5 illustrates an example of a workflow for holographic display based on a MPI content, according to an embodiment of the present disclosure. A content represented as an MPI or a sequence of MPI is input to the system. For simplicity in the representation, only a limited number of layers are represented in FIG. 5 but the MPI could have more layers, for instance 256 layers corresponding to 256 different levels of depth. An MPI pre-process is applied to convert the MPI into a format that is compressed using standard video coder. For instance, the MPI can be converted into an atlas of patches such as in the MIV compression scheme.

According to an embodiment of the present disclosure, an optimal positioning of each patch in each layer that minimizes the corresponding CGH calculation time at the decoder is determined. In an embodiment, such a determination of the positioning of the patches can be done on the encoder side. A set of metadata is thus built and sent to the decoder along with the encoded MPI. According to this embodiment, the decoder or rendering device of the CGH has only to re-arrange the patches of each layer when computing the CGH signal.

In a variant, the decoder or rendering device could also adapt the positioning of the patches received from the encoder, for instance to take into account display's characteristics that impacts the result of the propagation of the layers when reconstructing the CGH.

In another embodiment, the determination of the positioning of the patches can be done on the decoder side. According to this embodiment, the decoder receives the MIV bitstream with layered/MPI representation of the scene and determines a way to rearrange the content to reduce the image size for the layer. Thus, no additional metadata is required to be sent to the decoder. In yet another embodiment, one part of the determination of the positioning of the patches can be done at the encoder, and metadata relating to this part of the determination of the positioning is then sent to the decoder, so that the decoder can further proceed to finish the determination of the positioning. In this embodiment, the encoder analyzes the layers of the MPI representation and provides hints to the downstream entity (decoder or rendering device) on how to rearrange the content. For instance, the encoder sends metadata that allows identifying patches at extreme locations which should be moved, and that allows identifying position and size of open areas where such patches could be relocated. The decoder then uses the metadata as input, determine an arrangement of the patches based on the metadata, but without having to do a full analysis as in the previous embodiments.

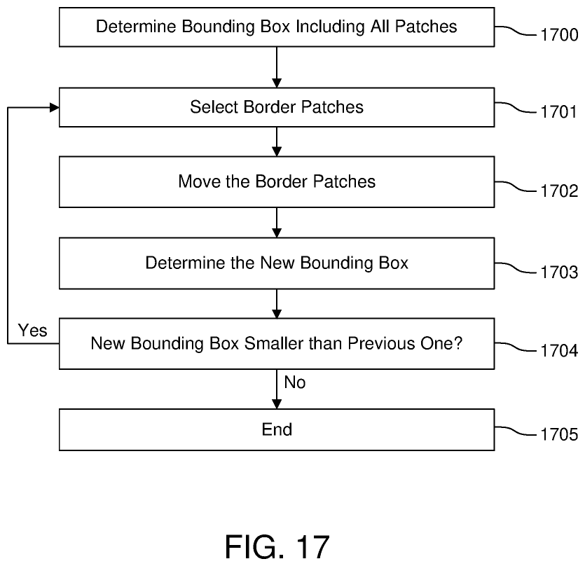

An example of a method for determining the new locations of the patches is described further below in reference with FIG. 17.

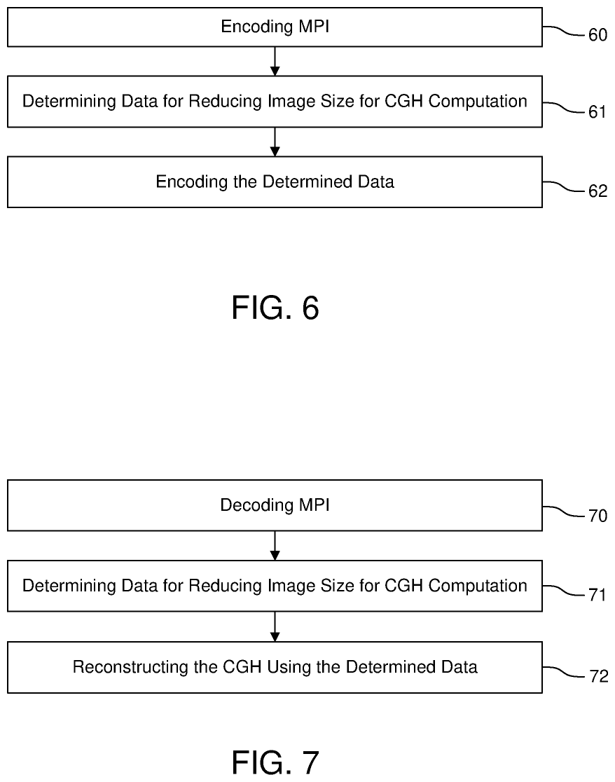

FIG. 6 illustrates a method for encoding MPI content that can be used for reconstructing a CGH, according to an embodiment. At 60, an MPI or a sequence of MPI in case of dynamic CGH, is encoded in a bitstream. For instance, the MPI content can be encoded using the MIV framework. According to the MIV framework, the layer images of the MPI are decomposed into a set atlas comprising patches. Data representative of the patches is encoded in the bitstream. The data associated to each patch comprises a first location that represents the location of the patch in an image of the multiple plane image. The first location is used for placing the content reconstructed from the patch in a 3D scene.

At 61, at least one item of information is determined. The item of information allows to determine for a patch, a second location for relocating the patch in a second image when a CGH is reconstructed at the decoder side using the second image. The item of information allows to relocate the patches in the second image such that the second image has a reduced size with respect to the first image.

At 62, the determined item of information is encoded in the bitstream with the MPI content. According to a variant, the item of information is encoded as syntax element associated with the patches in the bitstream. In other variants, the item of information is encoded as metadata, for instance in Supplemental Enhancement Information (SEI) message.

FIG. 7 illustrates a method for reconstructing a CGH from a received MPI content, according to an embodiment. At 70, an MPI or a sequence of MPI in case of dynamic CGH, is decoded from a bitstream. For instance, the MPI content has been encoded using the MIV framework. According to the MIV framework, the layer images of the MPI are decomposed into a set atlas comprising patches. Data representative of the patches is decoded from the bitstream. The data associated to each patch comprises a first location that represents the location of the patch in an image of the multiple plane image. The first location is used for placing the content reconstructed from the patch in a 3D scene.

At 71, second location for the patches is determined that allows relocating the patches in a second image that has a reduced size with respect to the first image. The second image is intended to be used for reconstructing the Computer-Generated Hologram.

According to an embodiment, at 72, the CGH is reconstructed using the second image.

The CGH can be reconstructed by the decoder or by another device, such that a rendering or display device. Data used for reconstructing the CGH is represented as MPI content. An MPI comprises a set of layers, each layer having a constant depth. Therefore, according to the embodiments described above, a second image is determined for each layer of the MPI. That is, each second image is associated to a same depth as the depth of the layer it is associated with. According to a variant, the reconstruction of the CGH is performed by propagating each one of the determined second pictures to a hologram plane, in a similar manner as if the second images were the images of the MPI. Then, the propagated data corresponding to each patch is arranged in the CGH using the first location associated to each patch as the first location allows to place the reconstructed content of the patch in the 3D space.

As explained above, the second image has a reduced size with respect to the first image. In other words, at least one of a width or height of the second image is smaller than a respective width or height of the first image. Determining the second image (either at the encoder or the decoder) is performed by a grouping of patches of the layer of the multiple plane image in an area or image that is smaller than an area or image in which the patches of the layer are initially placed. As will be discussed below, the grouping takes into account a surrounding area of each patch wherein patches shall not overlap. This surrounding area corresponds to the area of propagation of the patch content when propagating the patch data for computing the CGH.

A MPI is a collection of layers that represents a 3D scene at different depths. Since it has been acquired or generated from a given set of cameras having a limited Field of View (FOV), there are part of each layer that have empty pixels, meaning there is no corresponding information present at such depth for a given FOV. The more the number of layers, the higher the ratio of empty pixels in each layer. From a CGH calculation perspective, computing layers that have a huge number of empty pixels is not optimized. As seen with FIG. 4, there is an interest to limit the size of the layer to reduce the calculation time. An aim of the embodiments provided herein is to modify the layer structure by grouping patches on a smaller area than the whole picture.

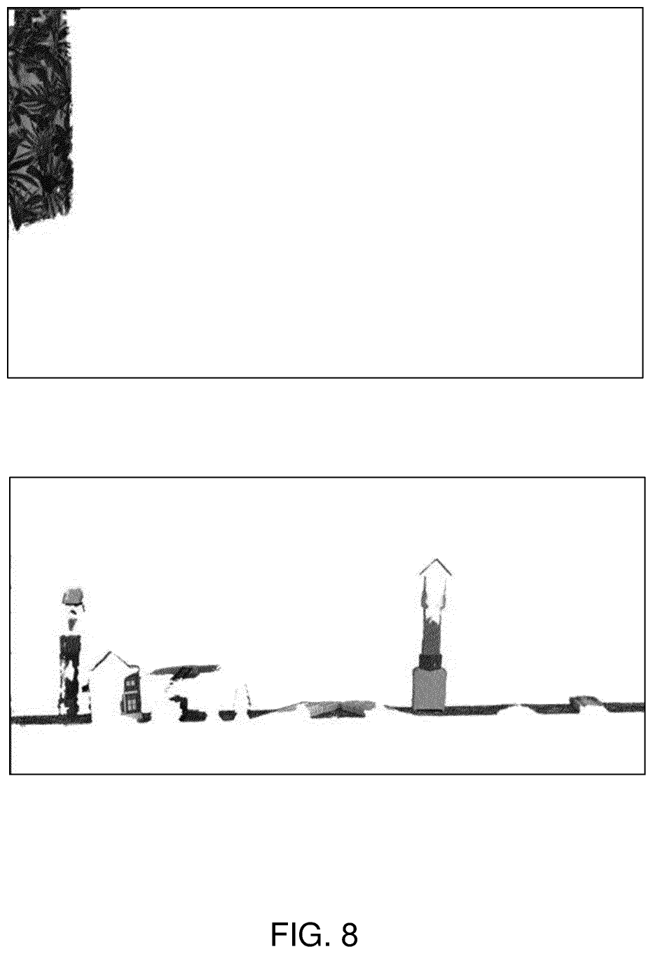

FIG. 8 represents two different layers of an MPI content where white parts are corresponding to empty pixels. One can see that white areas are very important but there are also isolated pixels in the right part of the first layer for instance. One may consider the whole frame for the CGH calculation to keep the quality at the end.

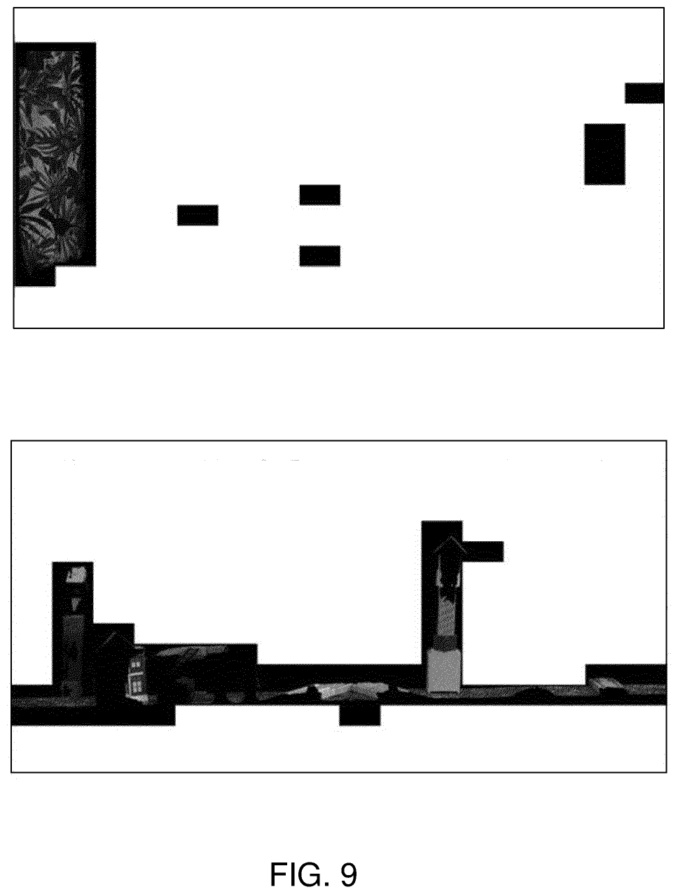

FIG. 9 represents the same layers wherein empty areas are in white and active areas having been expanded into rectangle bounding boxes. These rectangle areas can be seen as a set of patches as it is defined in the MPI/MIV context.

If the whole picture is calculated as a CGH, the time calculation is maximum. If separated areas are considered, the sum of all calculations may not be so low. The embodiments provided herein provide a way to group the different areas in an area that is smaller than the initial picture size. The reduction in pixel size of the image to be treated leads to a reduction of processing time and resources.

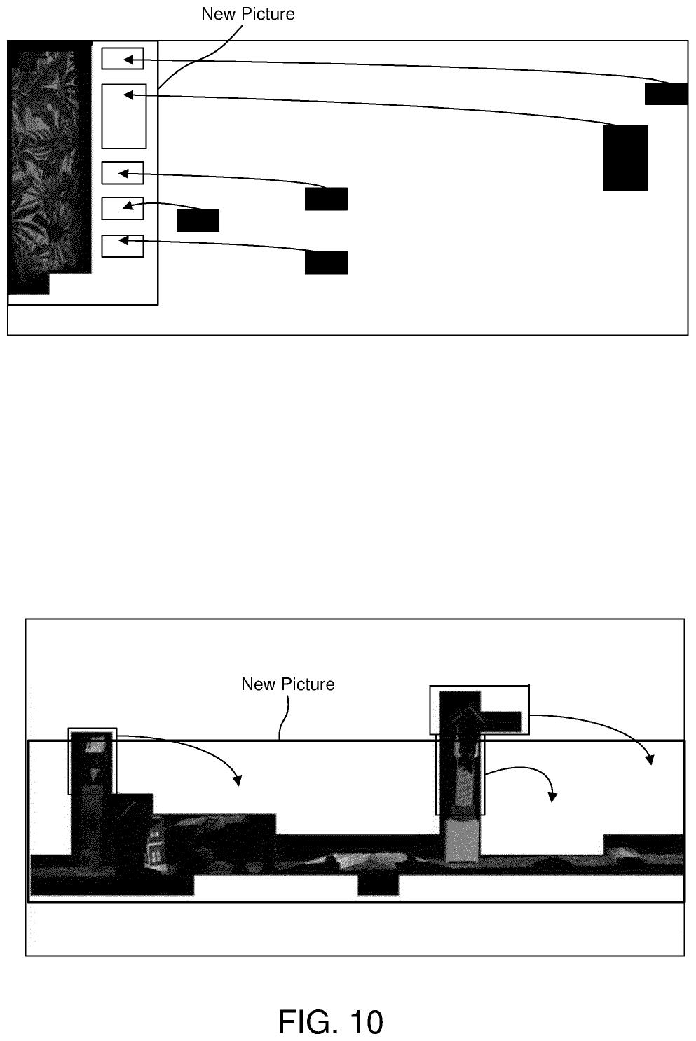

FIG. 10 illustrates examples of displacement (illustrated by the arrows) of the patches illustrated in FIG. 9 to determine a new picture that is smaller than the original picture. After the patches have been relocated to a new position in the new picture, the CGH calculation is faster since it is applied on a smaller picture. The smaller picture is obtained for example by relocating some or all of the patches in the empty are of the initial picture and resizing the width and height of the initial picture to only the active areas. On FIG. 10, the new picture area is shown with think lines. The CGH calculation corresponds to the propagation of the pixels in the layer to a given distance. Based on the processing parameters (pixel pitch, wavelength, and the propagation distance) patches must be separated to avoid overlap when propagated. This minimum separation of the patches in the picture (called Dmin in the following) is given by the following formula where z is the distance of the hologram, λ is the wavelength of the laser and p is the pixel pitch of the display used for displaying the hologram:

$$Dmin = z tan ( arcsin ( \frac{λ}{2 p} ) )$$

When the relocation positions of the patches is determined at the decoder side, the Dmin value can be determined from the display's characteristics. However, when the relocation positions of the patches is determined at the encoder side and sent to the decoder, these parameters are not known before transmission. According to this variant, a Dmin value is determined for a range of displays with a given pixel pitch and for a given distance.

For example, a numerical estimation for Dmin using a z=0.01 m and λ=500 nm and p=6.4 μm, provides a Dmin value of about 60 pixels.

Knowing this separation value for a given set of parameters, it is then possible to modify the position of the patches in a layer to reduce the size of this layer.

FIG. 10 illustrates the displacement that can be applied (arrows) to some patches to reduce the total size to be considered for the CGH calculation (thick lines frame). In these examples, the picture size to be considered for the calculation is strongly reduced. This operation can be repeated for each layer.

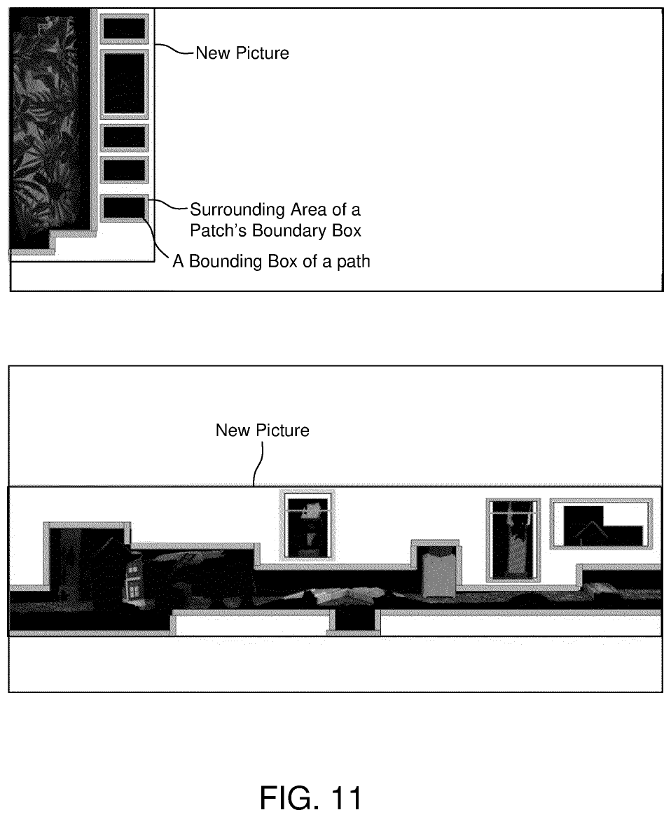

FIG. 11 illustrates the final size of each layer (new picture) and the new placement of each patch of the layer. The grey part surrounding each patch corresponds to the propagation of the content due to the CGH calculation wherein patches shall not overlap. The width of the area surrounding the patches is thus given by the determined Dmin value. It can be defined based on standard holographic display characteristics. In another variant, extreme values of Dmin can be used to ensure no overlap may happen.

Regarding the workflow described in FIG. 5, according to an embodiment, the displacement of the patches is only applied when reconstructing a CGH, that is the displacement of the patches is not applied before transmission. Only the coordinates of the future location for each patch or data that allows to determine such coordinates is associated to the data stream. In a variant, such information is inserted as metadata in the V3C/MIV specification as is described further below.

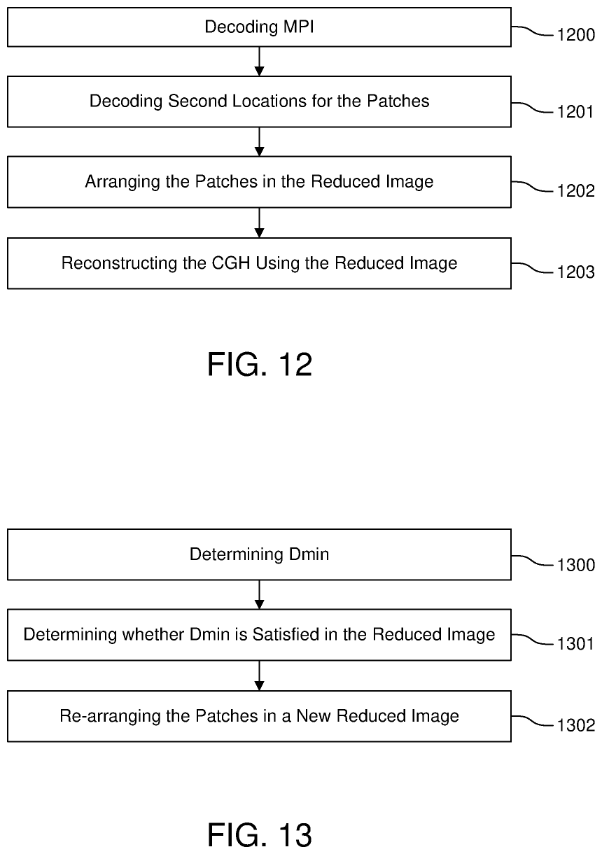

FIG. 12 illustrates a method for reconstructing a CGH from a received MPI content, according to an embodiment. At 1200, an MPI or a sequence of MPI in case of dynamic CGH, is decoded from a bitstream. For instance, the MPI content has been encoded using the MIV framework as described above.

According to this embodiment, the displacement of the patches to provide an image with a reduced size with respect to the image of a layer of the MPI is determined at the encoder, for instance using the method described above. The displacement of the patches is then coded in the bitstream with the MIV content.

At 1201, second locations for the patches are determined by decoding the data from the bitstream. For instance, the second locations are added to the MIV specification. In a variant, the transport of CGH using the MIV format is specified by adding a profile dedicated to the holographic use case. Such a profile would be derived from the existing “MIV Extended Restricted Geometry” profile (section A 4.2) dedicated to MPI content, by requiring in addition the new syntax elements for second patch locations.

In another variant, a separated HOLO extension of the V3C specification (ISO/IEC 23090-5:2021 (2E) Visual Volumetric Video-based Coding and Video-based Point Cloud Compression 2nd Edition) dedicated to the transport of CGH is specified, in a same manner as MIV or V-PCC are extensions of V3C and it is signalled in section 8.3.6.1.1 as underlined in the following table.

8.3.6.1.1 General atlas sequence parameter set RBSP syntax (V3C)

| | Descriptor |
|---|---|
| atlas_sequence_parameter_set_rbsp( ) { | |
| asps_atlas_sequence_parameter_set_id | ue(v) |
| asps_frame_width | ue(v) |
| asps_frame_height | ue(v) |
| asps_geometry_3d_bit_depth_minus1 | u(5) |
| asps_geometry_2d_bit_depth_minus1 | u(5) |
| (...) | |
| asps_extension_present_flag | u(1) |
| if( asps_extension_present_flag ) { | |
| asps_vpcc_extension_present_flag | u(1) |
| asps_miv_extension_present_flag | u(1) |
| asps_holo_extension_present_flag | u(1) |
| asps_extension_6bits | u(6) |
| } | |
| if( asps_vpcc_extension_present_flag ) | |
| asps_vpcc_extension( ) /* Specified in Annex H */ | |
| if( asps_miv_extension_present_flag ) | |
| asps_miv_extension( ) /* Specified in ISO/IEC 23090-12 */ | |
| if( asps_holo_extension_present_flag ) | |
| asps_holo_extension( ) /* Specified in xxx */ | |
| if( asps_extension_6bits ) | |
| while( more_rbsp_data( ) ) | |
| asps_extension_data_flag | u(1) |
| rbsp_trailing_bits( ) | |
| } | |

The asps_holo_extension_present_flag specifies that the asps_holo_extension( ) syntax structure is present.

The proposed HOLO extension of V3C contains syntax structures to extend the atlas sequence parameter set (ASPS), common atlas frame (OAF) and patch data unit (PDU) syntax structures. The MIV extension of OAF, which in particular specifies the camera parameters and depth quantization, can be reused as is for the HOLO extension.

The HOLO extension of ASPS only contains one flag, ashe_patch_constant_depth_flag, which is set to 1 to ensure that the transmitted CGH content is effectively an MPI content (where the depth is constant for a given layer), as specified in the table below:

| | Descriptor |
|---|---|
| asps_holo_extension( ) { | |
| ashe_patch_constant_depth_flag | u(1) |
| } | |

The patch data unit syntax of V3C is modified as underlined in the table below to allow the signaling of a HOLO extension.

8.3.7.3 Patch data unit syntax (V3C)

| | Descriptor |
|---|---|
| patch_data_unit( tileID, patchIdx ) { | |
| pdu_2d_pos_x[ tileID ][ patchIdx ] | ue(v) |
| pdu_2d_pos_y[ tileID ][ patchIdx ] | ue(v) |
| pdu_2d_size_x_minus1[ tileID ][ patchIdx ] | ue(v) |
| pdu_2d_size_y_minus1[ tileID ][ patchIdx ] | ue(v) |
| pdu_3d_offset_u[ tileID ][ patchIdx ] | u(v) |
| pdu_3d_offset_v[ tileID ][ patchIdx ] | u(v) |
| pdu_3d_offset_d[ tileID ][ patchIdx ] | u(v) |
| if( asps_normal_axis_max_delta_value_enabled_flag ) | |
| pdu_3d_range_d[ tileID ][ patchIdx ] | u(v) |
| pdu_projection_id[ tileID ][ patchIdx ] | u(v) |
| pdu_orientation_index[ tileID ][ patchIdx ] | u(v) |
| if( afps_lod_mode_enabled_flag ) { | |
| pdu_lod_enabled_flag[ tileID ][ patchIdx ] | u(1) |
| if( pdu_lod_enabled_flag[ tileID ][ patchIdx ] ) { | |
| pdu_lod_scale_x_minus1[ tileID ][ patchIdx ] | ue(v) |
| pdu_lod_scale_y_idc[ tileID ][ patchIdx ] | ue(v) |
| } | |
| } | |
| if( asps_plr_enabled_flag ) | |
| plr_data( tileID, patchIdx ) | |
| if( asps_miv_extension_present_flag ) | |
| pdu_miv_extension( tileID, patchIdx ) /* Specified in ISO/IEC 23090-12 */ | |
| if(asps_holo_extension_present_flag) | |
| pdu_holo_extension( tileID, patchIdx ) /* Specified in xxxx */ | |
| } | |

The HOLO extension of PDU specifies the second patch locations, as specified in the table below:

| | Descriptor |
|---|---|
| pdu_holo_extension( tileID, p ) { | |
| pdu_3d_offset_u_holo[ tileID ][ patchIdx ] | u(v) |
| pdu_3d_offset_v_holo[ tileID ][ patchIdx ] | u(v) |
| } | |

where pdu_3d_offset_u_holo[tileID][patchIdx] and pdu_3d_offset_v_holo[tileID][patchIdx] values represent The initial location of the patch (first location) in the image of the layer of the MPI to which the parch belongs to and the size of the patch is still given by the syntax of the patch data unit (PDU) above.
the horizontal and vertical shifts, respectively.

At 1202, the patches are arranged in the image using the decoded locations. Then, at 1203, the CGH is reconstructed using the image.

As explained above in reference with FIG. 7, the determination of the new image is performed for each layer of the MPI. At 1203, when reconstructing the CGH, each new image is propagated to the hologram plane. The propagated data corresponding to each patch is then arranged in the CGH using the first location associated to each patch that is coded in the patch data unit.

FIG. 13 illustrates a method for reconstructing a CGH from a received MPI content, according to a variant of the embodiment described with FIG. 12. According to this variant, at 1300, a separation value Dmin between the patches in the new image is determined. This separation value is based on at least one characteristic of the display that is used for displaying the reconstructed CGH, such as the pixel pitch or viewing distance. On the encoder side, these values are not available since it is not known in advance which display is used on the decoder side. The second locations determined on the encoder side may have assumed a default Dmin value determine for a range of displays, or assumed a worst case value or no Dmin value has been taken into account. According to the variant described here, a Dmin value is determined at the decoder side using the characteristics of the display used at the consumer side, using the formula given above.

At 1301, it is then checked whether the new image obtained from the arrangement of the patches using the second locations at 1202 satisfied the Dmin value, that is it is verified whether the patches in the new image are separated by at least a number of pixels equal to 2×Dmin. Considering a rectangular patch in the new image or a rectangular bounding box of the patch, the bounding box of the patch is surrounded by an area of width equal to Dmin. The bounding box of the patch and the surrounding area defines an extended bounding box (as illustrated on FIG. 11); The new image satisfies the separation criteria of the patches when none extended bounding box of patches overlap on each other.

When it is determined that at least two extended bounding boxes overlap, then at 1302, the overlapping patches are re-arranged in the new image, such that all patches arranges in the new image are separated by 2×Dmin. For instance, re-arrangement can be performed by extending the image size by a value provided by the amount of overlap of the patches, and all patches are shifted in the overlapping direction (horizontal, vertical or both) in the new image.

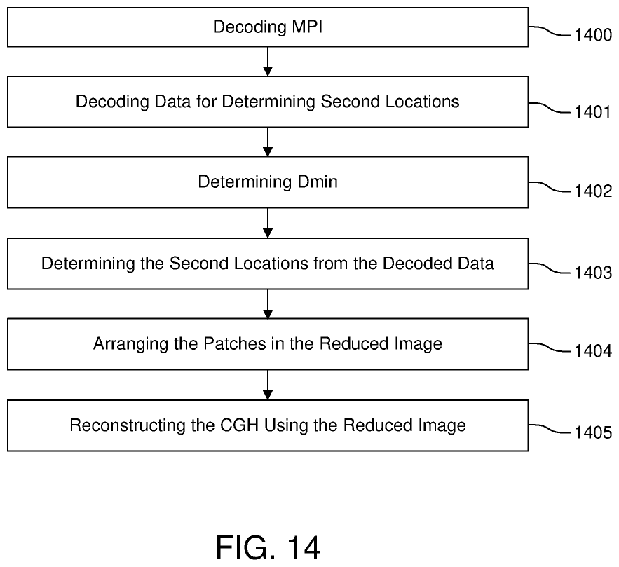

FIG. 14 illustrates a method for reconstructing a CGH from a received MPI content, according to another embodiment. According to this embodiment, the second locations of each patch are not transmitted, but hints to guide the arrangement of the patches in the new image are sent in the bitstream. At 1400, like for the previous embodiment, an MPI content is decoded from a received bitstream. At 1401, data for guiding the arrangement are decoded from the bitstream. For instance, this data can be data indicating areas in the new image wherein patches can be relocated, or data indicating patches that have to be relocated in the new image. For instance, patches to relocate can be identified by transmitting a flag in the patch data unit syntax of a current patch indicating whether the current patch has to be relocated or not. A list of empty areas can be transmitted at a higher level, image level or MPI level for instance.

At 1402, the Dmin value is determined using the characteristics of the display using the formula given above. At 1403, the relocation of the patches is determined using the Dmin value and decoded data (list of empty space, list of patches to relocate). This variant allows to speed up the determination of the relocations of the patches at the decoder side, while using a correct Dmin value. Once the relocations of the patches have been determined, the patches are arranged in the new image at 1404 and the CGH is reconstructed at 1405. As for the previous embodiments, determination of the relocations and patches arrangement in the new image is performed for each layer of the MPI before reconstructing the CGH.

FIG. 17 illustrates an example of a method for determining the new locations (or second locations) of patches. The method takes as input the patches and their locations in the image layer of the MPI and provides as output the new locations of the patches in the image of reduced size and the size of the image of reduced size. The method can be used either on the encoder side or the decoder side, as the locations of the patches in the image of MPI layer are known at both sides. At 1700, an image bounding box that includes all the patches in the image layer is determined. This image bounding box is a rectangular shape that includes all the patches of the image layer. The image bounding box size is smaller or equal to the picture size. For simplicity, the patches are considered in their own bounding box, as illustrated in FIG. 9. That is the patches also have a rectangular shape whose position and size in the image layer of the MPI is encoded in the bitstream in the patch data unit syntax when using the MIV framework.

At 1701, border patches of the image bounding box are selected. A border patch is to be understood as a patch at the border of the image bounding box. A border patch is a patch that has a same position as one border of the image bounding box. A border patch shares at least one common edge with the image bounding box determined at 1700.

At 1702, each border patch is moved to a nearest available position inside the image bounding box. An available position is an empty area inside the image bounding box. In a variant, determining an available position for a patch takes into account a distance between patches such that neighbors patches do no overlap after propagation. In this variant, thus an available position is an empty area inside the image bounding box and that is distant enough to not overlap with neighbors patches after propagation. When determining the available position for a patch, it is thus taken into account of the Dmin value determined using the formula given above. Depending on whether the method is performed at the encoder or the decoder, the Dmin value is determined as an estimation of a Dmin value based on characteristics of a range of displays or the Dmin value is determined based on the characteristics of the display used at the decoder side.

It may happen that no available position for a border patch can be found. In that case, the border patch is left at its last position in the image bounding box.

Once all the border patches have been relocated to an available position (whenever possible), the image bounding box is recalculated at 1703. At 1704, it is determined whether the new image bounding box is smaller than the previous image bounding box. If the new image bounding box is smaller, then the process iterates steps 1701 to 1704. If the new image bounding box is not smaller that the previous image bounding box, the process ends at 1705. The new image is provided as the last determined image bounding box.

The method described above for determining new locations for patches is illustrative of a simple method, more complex embodiments or variants of this embodiment can also be used.

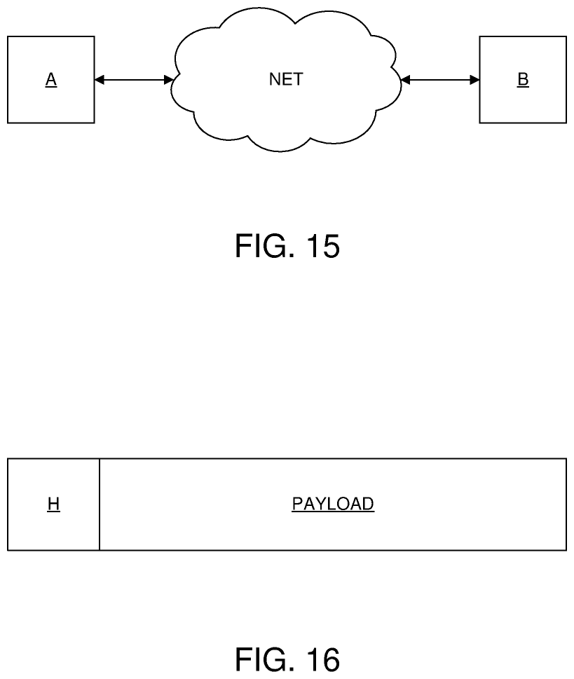

In an embodiment, illustrated in FIG. 15, in a transmission context between two remote devices A and B over a communication network NET, the device A comprises a processor in relation with memory RAM and ROM which are configured to implement a method for encoding an volumetric content as described with FIGS. 1-14 and 17 and the device B comprises a processor in relation with memory RAM and ROM which are configured to implement a method for decoding/reconstructing a CGH as described in relation with FIGS. 1-14 and 17.

In accordance with an example, the network is a broadcast network, adapted to broadcast/transmit encoded data representative of a CGH from device A to decoding devices including the device B.

A signal, intended to be transmitted by the device A, carries at least one bitstream comprising coded data representative of an MPI content and data representative of at least one item of information allowing to determine, for at least one patch of the MPI content, a second location for placing the patch in an image having a reduced size when reconstructing a Computer-Generated Hologram using said image. The bitstream may be generated from any embodiments of the present principles. In a variant, the bitstream comprises at least one of the following data: data indicating areas in the second image wherein patches can be relocated, data indicating patches that have to be relocated in the second image, at least one syntax element associated with the at least one patch, said at least one syntax element being representative of the second location, a syntax element indicating a presence of the second location in the bitstream, a syntax element indicating that pixels of the at least one patch have a constant depth, a syntax element indicating whether information for Computer Generated Hologram reconstruction is present in a bitstream or not.

FIG. 16 shows an example of the syntax of such a signal transmitted over a packet-based transmission protocol. Each transmitted packet P comprises a header H and a payload PAYLOAD. In some embodiments, the payload PAYLOAD may comprise coded video data encoded according to any one of the embodiments described above.

Various implementations involve decoding. “Decoding”, as used in this application, can encompass all or part of the processes performed, for example, on a received encoded sequence in order to produce a final output suitable for display. In various embodiments, such processes include one or more of the processes typically performed by a decoder, for example, entropy decoding, inverse quantization, inverse transformation, and differential decoding. In various embodiments, such processes also, or alternatively, include processes performed by a decoder of various implementations described in this application.

As further examples, in one embodiment “decoding” refers only to entropy decoding, in another embodiment “decoding” refers only to differential decoding, and in another embodiment “decoding” refers to a combination of entropy decoding and differential decoding. Whether the phrase “decoding process” is intended to refer specifically to a subset of operations or generally to the broader decoding process will be clear based on the context of the specific descriptions and is believed to be well understood by those skilled in the art.

Various implementations involve encoding. In an analogous way to the above discussion about “decoding”, “encoding” as used in this application can encompass all or part of the processes performed, for example, on an input video sequence in order to produce an encoded bitstream. In various embodiments, such processes include one or more of the processes typically performed by an encoder, for example, partitioning, differential encoding, transformation, quantization, and entropy encoding. In various embodiments, such processes also, or alternatively, include processes performed by an encoder of various implementations described in this application, for example.

As further examples, in one embodiment “encoding” refers only to entropy encoding, in another embodiment “encoding” refers only to differential encoding, and in another embodiment “encoding” refers to a combination of differential encoding and entropy encoding. Whether the phrase “encoding process” is intended to refer specifically to a subset of operations or generally to the broader encoding process will be clear based on the context of the specific descriptions and is believed to be well understood by those skilled in the art.

Note that the syntax elements as used herein are descriptive terms. As such, they do not preclude the use of other syntax element names.

This disclosure has described various pieces of information, such as for example syntax, that can be transmitted or stored, for example. This information can be packaged or arranged in a variety of manners, including for example manners common in video standards such as putting the information into an SPS, a PPS, a NAL unit, a header (for example, a NAL unit header, or a slice header), or an SEI message. Other manners are also available, including for example manners common for system level or application level standards such as putting the information into one or more of the following:
a. SDP (session description protocol), a format for describing multimedia communication sessions for the purposes of session announcement and session invitation, for example as described in RFCs and used in conjunction with RTP (Real-time Transport Protocol) transmission.
b. DASH MPD (Media Presentation Description) Descriptors, for example as used in DASH and transmitted over HTTP, a Descriptor is associated to a Representation or collection of Representations to provide additional characteristic to the content Representation.
c. RTP header extensions, for example as used during RTP streaming.
d. ISO Base Media File Format, for example as used in OMAF and using boxes which are object-oriented building blocks defined by a unique type identifier and length also known as ‘atoms’ in some specifications.
e. HLS (HTTP live Streaming) manifest transmitted over HTTP. A manifest can be associated, for example, to a version or collection of versions of a content to provide characteristics of the version or collection of versions.

When a figure is presented as a flow diagram, it should be understood that it also provides a block diagram of a corresponding apparatus. Similarly, when a figure is presented as a block diagram, it should be understood that it also provides a flow diagram of a corresponding method/process. The implementations and aspects described herein can be implemented in, for example, a method or a process, an apparatus, a software program, a data stream, or a signal. Even if only discussed in the context of a single form of implementation (for example, discussed only as a method), the implementation of features discussed can also be implemented in other forms (for example, an apparatus or program). An apparatus can be implemented in, for example, appropriate hardware, software, and firmware. The methods can be implemented in, for example, a processor, which refers to processing devices in general, including, for example, a computer, a microprocessor, an integrated circuit, or a programmable logic device. Processors also include communication devices, such as, for example, computers, cell phones, portable/personal digital assistants (“PDAs”), and other devices that facilitate communication of information between end-users.

Reference to “one embodiment” or “an embodiment” or “one implementation” or “an implementation”, as well as other variations thereof, means that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout this application are not necessarily all referring to the same embodiment.

Additionally, this application may refer to “determining” various pieces of information. Determining the information can include one or more of, for example, estimating the information, calculating the information, predicting the information, or retrieving the information from memory.

Further, this application may refer to “accessing” various pieces of information. Accessing the information can include one or more of, for example, receiving the information, retrieving the information (for example, from memory), storing the information, moving the information, copying the information, calculating the information, determining the information, predicting the information, or estimating the information.

Additionally, this application may refer to “receiving” various pieces of information. Receiving is, as with “accessing”, intended to be a broad term. Receiving the information can include one or more of, for example, accessing the information, or retrieving the information (for example, from memory). Further, “receiving” is typically involved, in one way or another, during operations such as, for example, storing the information, processing the information, transmitting the information, moving the information, copying the information, erasing the information, calculating the information, determining the information, predicting the information, or estimating the information.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C and” at least one of A, B, and C, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as is clear to one of ordinary skill in this and related arts, for as many items as are listed.

As will be evident to one of ordinary skill in the art, implementations can produce a variety of signals formatted to carry information that can be, for example, stored or transmitted. The information can include, for example, instructions for performing a method, or data produced by one of the described implementations. For example, a signal can be formatted to carry the bitstream of a described embodiment. Such a signal can be formatted, for example, as an electromagnetic wave (for example, using a radio frequency portion of spectrum) or as a baseband signal. The formatting can include, for example, encoding a data stream and modulating a carrier with the encoded data stream. The information that the signal carries can be, for example, analog or digital information. The signal can be transmitted over a variety of different wired or wireless links, as is known. The signal can be stored on a processor-readable medium.

A number of embodiments have been described. Features of these embodiments can be provided alone or in any combination, across various claim categories and types. Further, embodiments can include one or more of the following features, devices, or aspects, alone or in any combination, across various claim categories and types:
a method/an apparatus for reconstructing a Computer-Generated Hologram from a multiple plane image wherein reconstructing the Computer-Generated Hologram comprises decoding data representative of at least one patch of at least one layer of the multiple plane image, said data comprising a first location for placing said patch in a first image of the multiple plane image, said first location being used for placing reconstructed content of said patch in a 3D scene, determining for said at least one patch a second location for placing said patch in a second image, said second image being intended to be used for determining the Computer-Generated Hologram,
a method/an apparatus for encoding MPI content suitable for CGH reconstruction, comprising encoding in a bitstream, data representative of at least one patch of at least one layer of a multiple plane image, said data comprising a first location for placing said patch in a first image of the multiple plane image, said first location being used for placing reconstructed content of said patch in a 3D scene, determining at least one item of information allowing to determine, for at least said at least one patch, a second location for placing said patch in a second image when reconstructing a Computer-Generated Hologram using said second image, encoding said at least one item of information in the bitstream,
a method/an apparatus wherein at least one of a width or height of the second image is smaller than a respective width or height of the first image,
a method/an apparatus wherein determining the second location comprises encoding/decoding at least one syntax element associated with the patch, said at least one syntax element being representative of the second location.
a method/an apparatus wherein the patches are arranged into the second image using the second location, the Computer-Generated Hologram is reconstructed based at least on the second image and on the first location of said patch,
a method/an apparatus wherein determining the second location comprises determining a separation value between patches in said second image, said separation value being based on at least one characteristic of at least one display used for displaying the reconstructed Computer-Generated Hologram,
a method/an apparatus wherein the at least one characteristic of the at least one display is at least one of a pixel pitch of the display or a viewing distance of the Computer-Generated Hologram from the display,
a method/an apparatus wherein responsive to a determination that at least two patches arranged in the second image using the determined second locations are not separated by the determined separation value, at least the at least two patches are re-arranged in the second image such that all patches arranged in the second image are separated by the determined separation value,
a method/an apparatus wherein determining the second location comprises encoding/decoding at least one of data indicating areas in the second image wherein patches can be relocated, or data indicating patches that have to be relocated in the second image,
a method/an apparatus wherein determining the second location is based on the encoded/decoded data,
a method/an apparatus wherein arranging the at least one patch into the second image using the second location takes into account said determined separation value,
a method/an apparatus wherein reconstructing the Computer-Generated Hologram comprises propagating said second image to a hologram plane, said second image having a same depth as said first image of the multiple plane image, arranging in the Computer-Generated Hologram, the propagated data corresponding to said patch using the first location of said patch,
a method/an apparatus wherein determining the second location for the patch is based on a grouping of patches of said at least one layer of the multiple plane image in an area that is smaller than an area in which the patches of the at least one layer are placed,
a method/an apparatus wherein the grouping takes into account a surrounding area of each patch wherein patches shall not overlapped, the surrounding area corresponding to a propagation zone determined when reconstructing a Computer Generated Hologram from the patches of the at least one layer,
a method/an apparatus wherein the at least one syntax element comprises an horizontal offset and a vertical offset,
a method/an apparatus wherein a syntax element indicating a presence of the second location in a bitstream is decoded from/encoded in a bitstream,
a method/an apparatus wherein a syntax element indicating that pixels of the at least one patch have a constant depth is decoded/encoded from/in a bitstream,
a method/an apparatus wherein a syntax element indicating whether information for Computer Generated Hologram reconstruction is present in a bitstream or not is decoded from/encoded in a bitstream,
   a bitstream comprising data representative of at least one patch of at least one layer of a multiple plane image, said data comprising a first location for placing said patch in a first image of the multiple plane image, said first location being used for placing reconstructed content of said patch in a 3D scene, data representative of at least one item of information allowing to determine, for at least said at least one patch, a second location for placing said patch in a second image when reconstructing a Computer-Generated Hologram using said second image,
a method/an apparatus/a bitstream wherein the at least one item of information comprises at least one of:
   data indicating areas in the second image wherein patches can be relocated,
data indicating patches that have to be relocated in the second image,
at least one syntax element associated with the at least one patch, said at least one syntax element being representative of the second location,
a syntax element indicating a presence of the second location in the bitstream,
a syntax element indicating that pixels of the at least one patch have a constant depth,
   a syntax element indicating whether information for Computer Generated Hologram reconstruction is present in a bitstream or not.
a computer readable medium comprising a bitstream according to any one of the above cited embodiments,
a computer readable storage medium having stored thereon instructions for causing one or more processors to perform the method according to any one of the above cited embodiments,
a computer program product including instructions which, when the program is executed by one or more processors, causes the one or more processors to carry out the method according to any one of the above cited embodiments,
a device comprising an apparatus according to according to any one of the above cited embodiments, at least one of (i) an antenna configured to receive a signal, the signal including data representative of at least one patch of at least one layer of a multiple plane image, said data comprising a first location for placing said patch in a first image of the multiple plane image, said first location being used for placing reconstructed content of said patch in a 3D scene, (ii) a band limiter configured to limit the received signal to a band of frequencies that includes the data representative of at least one patch of at least one layer of a multiple plane image, or (iii) a display configured to display the Computer-Generated Hologram,
a device having a holographic display and comprising an apparatus according to according to any one of the above cited embodiments,
a device comprising an apparatus according to according to any one of the above cited embodiments, comprising any one of a TV, a cell phone, a tablet or a Set Top Box.
a transmitting apparatus comprising an accessing unit configured to access data comprising a signal that includes a bitstream to according to any one of the above cited embodiments, a transmitter configured to transmit the accessed data,
a method for accessing data comprising a signal that includes a bitstream according to any one of the above cited embodiments, and transmitting the accessed data.

1. A method, comprising reconstructing a computer-generated hologram from a multiple plane image, wherein reconstructing the computer-generated hologram comprises:
decoding data representative of at least one patch of at least one layer of the multiple plane image, the data comprising a first location for placing the patch in a first image of the multiple plane image, the first location being used for placing reconstructed content of the patch in a 3D scene; and
determining for the at least one patch a second location for placing the at least one patch in a second image, the second image having a reduced size than the first image and being intended to be used for determining the computer-generated hologram.

2. An apparatus comprising one or more processors configured for reconstructing a computer-generated hologram from a multiple plane image, wherein being configured for reconstructing the computer-generated hologram comprises being configured for:
decoding data representative of at least one patch of at least one layer of the multiple plane image, the data comprising a first location for placing the patch in a first image of the multiple plane image, the first location being used for placing reconstructed content of the patch in a 3D scene; and
determining for the at least one patch a second location for placing the at least one patch in a second image, the second image having a reduced size than the first image and being intended to be used for determining the computer-generated hologram.

3. The apparatus of claim 2, wherein at least one of a width or height of the second image is smaller than a respective width or height of the first image.

4. The apparatus of claim 2, wherein being configured for determining the second location comprises being configured for decoding at least one syntax element associated with the patch, the at least one syntax element being representative of the second location.

5. The apparatus of claim 2, the one or more processors being further configured for:
arranging the at least one patch into the second image using the second location; and
reconstructing the computer-generated hologram based at least on the second image and on the first location of the at least one patch.

6. The method of claim 1, wherein determining the second location comprises:
determining a separation value between patches in the second image, the separation value being based on at least one characteristic of at least one display used for displaying the reconstructed computer-generated hologram.

7. The method of claim 6, wherein the at least one characteristic of the at least one display is at least one of a pixel pitch of the display or a viewing distance of the computer-generated hologram from the display.

8. The method of claim 6, further comprising:
responsive to a determination that at least two patches arranged in the second image using the determined second locations are not separated by the determined separation value, re-arranging at least the at least two patches in the second image such that all patches arranged in the second image are separated by the determined separation value.

9. The method of claim 1, wherein determining the second location comprises:
decoding at least one of data indicating areas in the second image wherein patches can be relocated, or data indicating patches that have to be relocated in the second image.

10. (canceled)

11. The method of claim 6, wherein arranging the at least one patch into the second image using the second location takes into account the determined separation value.

12. The apparatus of claim 5, wherein being configured for reconstructing the computer-generated hologram comprises:
propagating the second image to a hologram plane, the second image having a same depth as the first image of the multiple plane images; and
arranging, in the computer-generated hologram, propagated data corresponding to the at least one patch using the first location of the at least one patch.

13. The method of claim 1, wherein determining the second location for the at least one patch is based on a grouping of patches of the at least one layer of the multiple plane image in an area that is smaller than an area in which the patches of the at least one layer are placed.

14. The method of claim 13, wherein the grouping takes into account a surrounding area of each patch wherein patches shall not overlap, the surrounding area corresponding to a propagation zone determined when reconstructing a computer-generated hologram from the patches of the at least one layer.

15. The apparatus of claim 4, wherein the at least one syntax element comprises a horizontal offset and a vertical offset.

16-18. (canceled)

19. A method, comprising:
encoding in a bitstream, data representative of at least one patch of at least one layer of a multiple plane image, the data comprising a first location for placing the patch in a first image of the multiple plane image, the first location being used for placing reconstructed content of the patch in a 3D scene;
determining at least one item of information allowing to determine, for at least the at least one patch, a second location for placing the at least one patch in a second image when reconstructing a computer-generated hologram using the second image, the second image having a reduced size than the first image; and
encoding the at least one item of information in the bitstream.

20. An apparatus comprising one or more processors configured to:
encode in a bitstream, data representative of at least one patch of at least one layer of a multiple plane image, the data comprising a first location for placing the patch in a first image of the multiple plane image, the first location being used for placing reconstructed content of the patch in a 3D scenes; and
determine at least one item of information allowing to determine, for at least the at least one patch, a second location for placing the at least one patch in a second image when reconstructing a computer-generated hologram using the second image, the second image having a reduced size than the first image,
encode the at least one item of information in the bitstream.

21. A computer readable medium comprising a bitstream including:
data representative of at least one patch of at least one layer of a multiple plane image, the data comprising a first location for placing the patch in a first image of the multiple plane image, the first location being used for placing reconstructed content of the patch in a 3D scene; and
data representative of at least one item of information allowing to determine, for at least the at least one patch, a second location for placing the at least one patch in a second image when reconstructing a computer-generated hologram using the second image, the second image having a reduced size than the first image.

22. The computer readable medium of claim 21, wherein the at least one item of information comprises at least one of:
data indicating areas in the second image wherein patches can be relocated;
data indicating patches that have to be relocated in the second image;
at least one syntax element associated with the at least one patch, the at least one syntax element being representative of the second location;
a syntax element indicating a presence of the second location in the bitstream;
a syntax element indicating that pixels of the at least one patch have a constant depth; and
a syntax element indicating whether information for computer-generated hologram reconstruction is present in a bitstream or not.

23. (canceled)

24. A computer readable storage medium having stored thereon instructions for causing one or more processors to perform the method of claim 1.

25. (canceled)

26. The apparatus of claim 2, further comprising:
at least one of (i) an antenna configured to receive a signal, the signal including data representative of at least one patch of at least one layer of a multiple plane image, the data comprising a first location for placing the patch in a first image of the multiple plane image, the first location being used for placing reconstructed content of the patch in a 3D scene, (ii) a band limiter configured to limit the received signal to a band of frequencies that includes the data representative of at least one patch of at least one layer of a multiple plane image, or (iii) a display configured to display the computer-generated hologram.

27. The apparatus of claim 26, wherein the display is a holographic display.

28. The apparatus of claim 26, comprising a television, a cell phone, a tablet or a set top box.

29. The apparatus of claim 20 further comprising:
an accessing unit configured to access data comprising a signal that includes a computer readable medium according to claim 21,
a transmitter configured to transmit the accessed data.

30. (canceled)
